(19) United States
(12) Patent Application Publication
(10) Pub. No.: US 2014/0151095 A1
(43) Pub. Date: Jun. 5, 2014

(54) PRINTED CIRCUIT BOARD AND METHOD FOR MANUFACTURING THE SAME

(71) Applicant: SAMSUNG ELECTRO-MECHANICS CO., LTD., Suwon (KR)

(72) Inventors: Suk Hyeon Cho, Suwon (KR); Tae Hong Min, Suwon (KR); Seung Yeop Kook, Suwon (KR); Jung Han Lee, Suwon (KR); Hye Jin Kim, Suwon (KR)

(73) Assignee: SAMSUNG ELECTRO-MECHANICS CO., LTD., Suwon (KR)

(21) Appl. No.: 14/097,036

(22) Filed: Dec. 4, 2013

(30) Foreign Application Priority Data
Dec. 5, 2012 (KR) 10-2012-0140480

(51) Int. Cl. H05K 1/03; H05K 3/42; H05K 3/28

(52) U.S. Cl. CPC H05K 1/0306; H05K 3/28; H05K 3/42
USPC 174/255; 29/846; 29/852

(57) ABSTRACT

Disclosed herein is a printed circuit board, including: a composite sheet including an insulating material and a glass plate bonded to the insulating material; and a circuit layer formed on the composite sheet.

### CROSS REFERENCE TO RELATED APPLICATION

This application claims the benefit of Korean Patent Application No. 10-2012-0140480, filed on Dec. 5, 2012, entitled “Printed Circuit Board And Method For Manufacturing The Same”, which is hereby incorporated by reference in its entirety into this application.

### BACKGROUND OF THE INVENTION

1. Technical Field

The present invention relates to a printed circuit board and a method for manufacturing the same.

2. Description of the Related Art

With the slimness of portable electronic devices, an attempt to reduce a thickness of internal parts has been continuously conducted.

However, when a thickness of a printed circuit board among the internal parts is reduced, the printed circuit board may be sagged or warped by being heated or cooled according to a reflow process.

Therefore, according to the prior art, a method of inserting metal into a printed circuit board to improve a heat dissipation characteristic while reducing a coefficient of thermal expansion and increasing rigidity has been used; however the method needs to previously remove metal at a portion at which vias is formed from the corresponding metal in order to insulate between the vias for interlayer electrical connection, which may lead to a problem of making a process complex and increasing manufacturing costs.

Meanwhile, the printed circuit board into which the metal is inserted according to the prior art has been disclosed in U.S. Pat. No. 6,711,812.

### SUMMARY OF THE INVENTION

The present invention has been made in an effort to provide a printed circuit board in which there is no roughness at an interface between the printed circuit board and a circuit pattern to easily implement circuits having less signal noise and an ultrafine pitch thereon, and a method for manufacturing the same.

Further, the present invention has been made in an effort to provide a printed circuit board of which the deformed degree depending on a change in temperature and humidity is minimized, and a method for manufacturing the same.

In addition, the present invention has been made in an effort to provide a printed circuit board having a thin thickness and excellent rigidity, and a method for manufacturing the same.

According to a preferred embodiment of the present invention, there is provided a printed circuit board, including: a composite sheet including an insulating material and a glass plate bonded to the insulating material; and a circuit layer formed on the composite sheet.

The composite sheet may have a structure in which the glass plate is bonded to one surface or both surfaces of the insulating material.

The composite sheet may have a structure in which the insulating material is bonded to one surface or both surfaces of the glass plate.

The circuit layer may include: a circuit pattern formed on the composite sheet; and a via formed to penetrate through the composite sheet.

The circuit layer may include: a seed layer formed on a surface of the composite sheet; and a plating layer formed on the seed layer.

The seed layer may be made of any one selected from a group consisting of titanium (Ti), aluminum (Al), copper (Cu), molybdenum (Mo), nickel (Ni), silver (Ag), zinc (Zn), carbon (C) or an alloy thereof.

The seed layer may include: a first seed layer formed on the surface of the composite sheet; and a second seed layer formed on the first seed layer.

The insulating material may be made of polymer having heat resistance.

The insulating material may include any one selected from a group consisting of liquid crystal polymer (LCP), polyethylene terephthalate (PET), polyethylene naphthalate (PEN), polyurethane (PU), epoxy in which glass fabric is impregnated, and polyimide.

According to another preferred embodiment of the present invention, there is provided a method for manufacturing a printed circuit board, including: preparing a composite sheet in which a glass plate is bonded to an insulating material; forming a seed layer on the composite sheet; forming a plating resist having an opening for circuit formation on the seed layer; forming a plating layer in the opening by a plating process; and removing the plating resist.

The preparing of the composite sheet may include: disposing the glass plate on one surface or both surfaces of the insulating material; and bonding the insulating material to the glass plate by a heating process and a pressing process.

The preparing of the composite sheet may include: disposing the insulating material on one surface or both surfaces of the glass plate; and bonding the insulating material to the glass plate by a heating process and a pressing process.

The forming of the seed layer may be performed by a sputtering method.

The forming of the seed layer may include: forming a first seed layer on a surface of the composite sheet; and forming a second seed layer on the first seed layer.

The method for manufacturing a printed circuit board may further include: prior to the forming of the seed layer, machining a via hole penetrating through the composite sheet.

The machining of the via hole may be performed using a laser drill.

The method for a printed circuit may further include: after the machining of the via hole, cleaning the surface of the composite sheet and an inside of the via hole.

The cleaning may be performed by dry etching or wet etching.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view illustrating a structure of a printed circuit board according to a preferred embodiment of the present invention;

FIG. 2 is a cross-sectional view illustrating a structure of a printed circuit board according to another preferred embodiment of the present invention; and

FIGS. 3 to 8 are process cross-sectional views sequentially illustrating a method for manufacturing a printed circuit board according to a preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

Printed Circuit Board

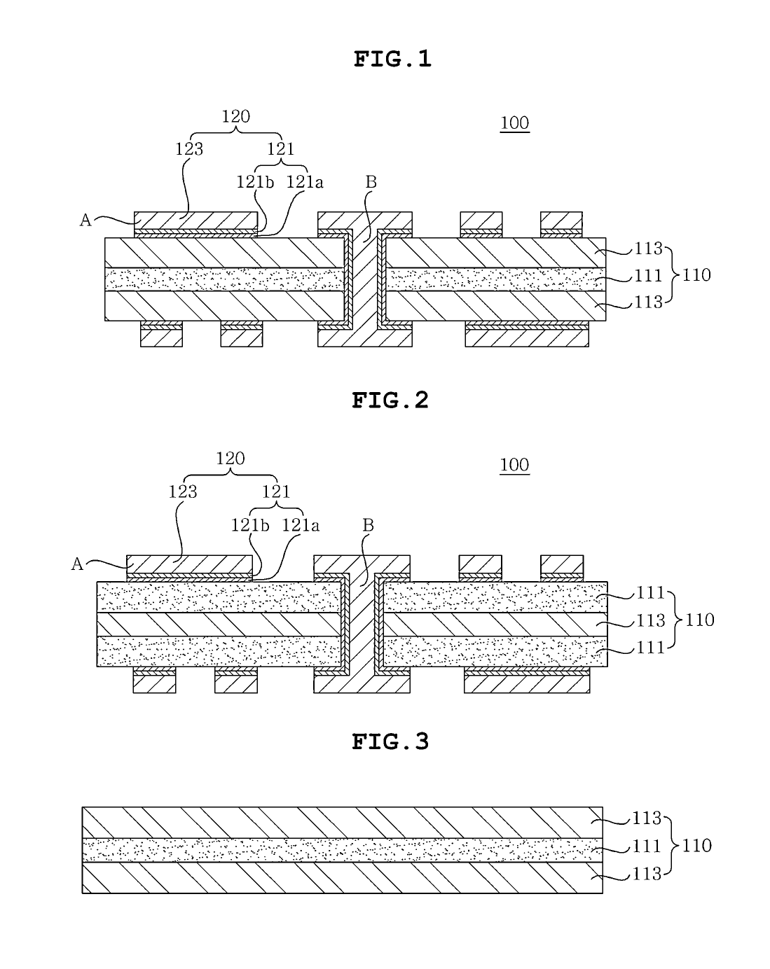

FIG. 1 is a cross-sectional view showing a structure of a printed circuit board according to the preferred embodiment of the present invention.

Referring to FIG. 1, a printed circuit board 100 according to a preferred embodiment of the present invention includes an insulating material 111, a composite sheet 110 including a glass plate 113 which is bonded to the insulating material 111, and a circuit layer 120 which is formed on the composite sheet 110.

According to the preferred embodiment of the present invention, the insulating material 111 may be made of polymer having heat resistance, but the preferred embodiment of the present invention is not particularly limited thereto.

Herein, the polymer may be any one selected from a group consisting of liquid crystal polymer (LCP), polyethylene terephthalate (PET), polyethylene naphthalate (PEN), polyurethane (PU), epoxy in which glass fabric is impregnated, and polyimide, but the preferred embodiment of the present invention is not particularly limited thereto.

FIG. 1 illustrates the composite sheet 100 in which the glass plates 113 are bonded to both surfaces of the insulating material 111, which is only one example, and therefore the glass plate 113 may be bonded to only one surface of the insulating material 111.

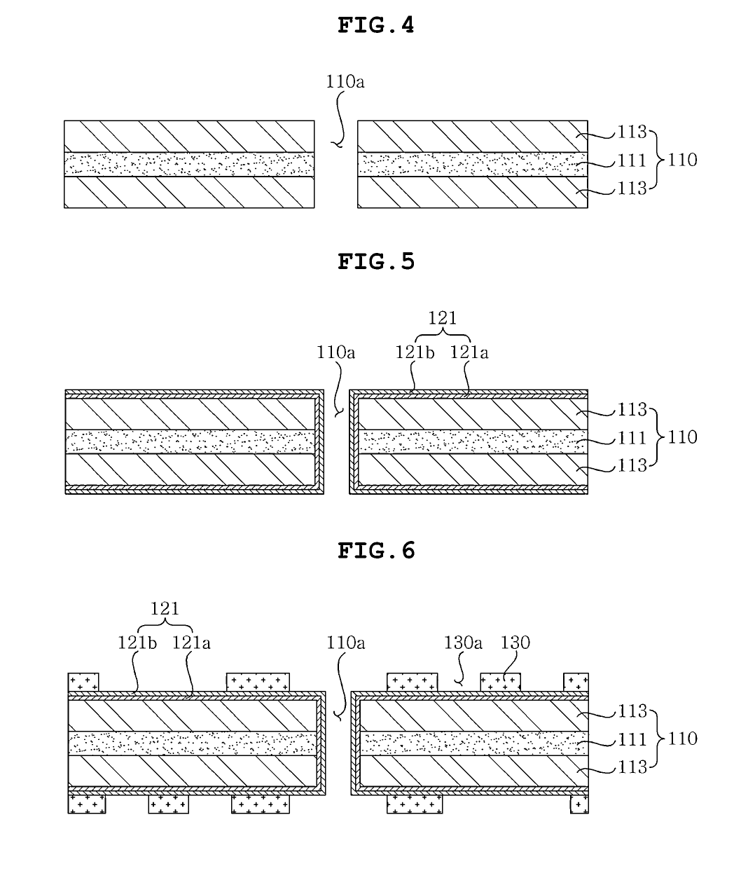

Further, as illustrated in FIG. 2, the insulating materials 111 may also be bonded to both surfaces of the glass plate 113.

As such, the insulating material 111 performs a shock absorption function by bonding the insulating material 111 to the glass plate 113 to be able to prevent the glass plate from being damaged during a manufacturing process.

Meanwhile, FIGS. 1 and 2 illustrates that the insulating material 111 is configured of a single layer, which is only one example, and therefore the insulating material may also be configured of multi layers of at least two layers.

As such, the printed circuit board 100 according to the preferred embodiment of the present invention is formed by using the composite sheet 110 in which the glass plates 113 having excellent rigidity are bonded to both surfaces of the insulating material 111 or the composite sheet 110 in which the insulating materials 111 are bonded to both surfaces of the glass plate 113, such that the printed circuit board 100 may have more excellent rigidity and have less deformation depending on a change in temperature and humidity than the printed circuit board formed by using the sheet made only of the insulating material, such as resin.

According to the preferred embodiment of the present invention, the circuit layer 120 may include a circuit pattern A which is formed on the composite sheet 110 and a via B which is formed to penetrate through the composite sheet 110, but the preferred embodiment of the present invention is not particularly limited thereto.

In detail, as illustrated in FIG. 1, the circuit layer 120 may include the circuit pattern A which is formed on the glass plate 113 of the composite sheet 110 and a via B which is formed to penetrate through the composite sheet 110.

In detail, as illustrated in FIG. 2, the circuit layer 120 may include the circuit pattern A which is formed on the insulating material 111 of the composite sheet 110 and a via B which is formed to penetrate through the composite sheet 110.

In this case, the circuit layer 120 may include a seed layer 121 which is formed on a surface of the composite sheet 110 and a plating layer 123 which is formed on the seed layer 121, but the preferred embodiment of the present invention is not particularly limited thereto.

According to the preferred embodiment of the present invention, the seed layer 121 may be made of any one selected from a group consisting of titanium (Ti), aluminum (Al), copper (Cu), molybdenum (Mo), nickel (Ni), silver (Ag), zinc (Zn), carbon (C) or an alloy thereof, but the preferred embodiment of the present invention is not particularly limited thereto.

Further, the plating layer 123 may be made of copper (Cu), but the preferred embodiment of the present invention is not particularly limited thereto.

Meanwhile, according to the preferred embodiment of the present invention, the seed layer 121 may include a first seed layer 121a which is formed on the surface of the composite sheet 110 and a second seed layer 121b which is formed on the first seed layer 121a, but the preferred embodiment of the present invention is not particularly limited thereto.

In this case, the first seed layer 121a and the second seed layer 121b may each be made of any one selected from a group consisting of titanium (Ti), aluminum (Al), copper (Cu), molybdenum (Mo), nickel (Ni), silver (Ag), zinc (Zn), carbon (C) or an alloy thereof, but the preferred embodiment of the present invention is not particularly limited thereto.

Further, although not illustrated in FIGS. 1 and 2, a multi-layer printed circuit board in which a build-up layer (not illustrated) including a plurality of insulating layers and a plurality of circuit layers is formed on the composite sheet 110 formed with the circuit layer 120 may be formed.

In this case, like the above-mentioned composite sheet 110, the plurality of insulating layers may have a structure in which the glass plate is bonded to one surface or both surfaces of the insulating material made of polymer having heat resistance or a structure in which the insulating material is bonded to one surface or both surfaces of the glass plate, but the preferred embodiment of the present invention is not particularly limited thereto. Therefore, any material which is widely used as the insulating layer in the art may be used.

As such, according to the printed circuit board 100 according to the preferred embodiment of the present invention, the circuit layer 120 is formed on the glass plate 113 having a smooth surface to prevent roughness from being formed at an interface between the glass plate 113 and the circuit layer 120, thereby implementing a circuit having less signal noise and an ultrafine pitch.

Further, in terms of characteristics of glass, a modulus is kept even at high temperature, such that the printed circuit board 100 according to the preferred embodiment of the present invention is less deformed against the change in temperature and humidity.

Method for Manufacturing Printed Circuit Board

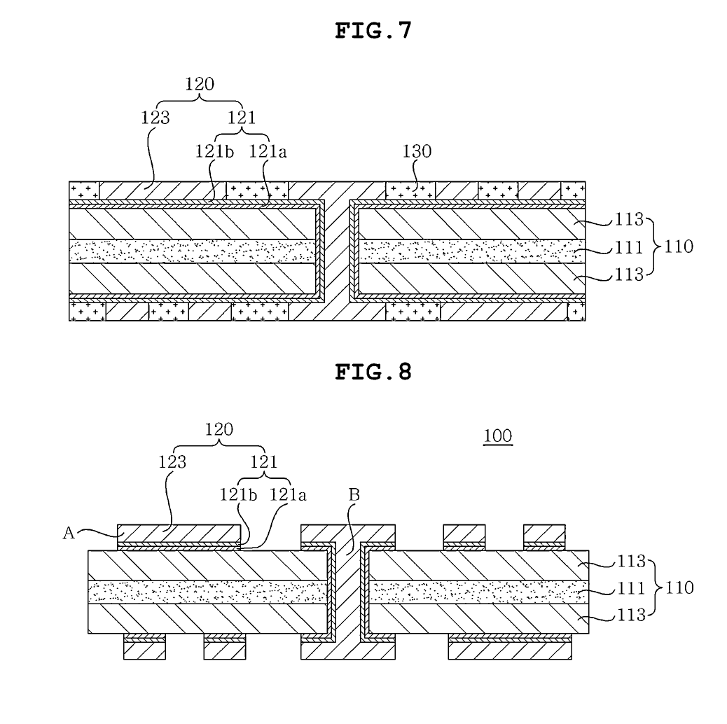

FIGS. 3 to 8 are process cross-sectional views sequentially illustrating a method for manufacturing a printed circuit board according to a preferred embodiment of the present invention.

Meanwhile, a drawing illustrating a method for manufacturing the printed circuit board of FIG. 2 is not separately illustrated, but only a process of preparing the composite sheet 110 is different from the preferred embodiment of the present invention and the following processes are the same as the preferred embodiment of the present invention.

Referring first to FIG. 3, the composite sheet 110 in which the glass plate 113 is bonded to the insulating material 111 is prepared.

According to the preferred embodiment of the present invention, the insulating material 111 may be made of polymer having heat resistance, but the preferred embodiment of the present invention is not particularly limited thereto.

Herein, the polymer may be any one selected from a group consisting of liquid crystal polymer (LCP), polyethylene terephthalate (PET), polyethylene naphthalate (PEN), polyurethane (PU), epoxy in which glass fabric is impregnated, and polyimide, but the preferred embodiment of the present invention is not particularly limited thereto.

FIG. 1 illustrates the composite sheet 110 in which the glass plates 113 are bonded to both surfaces of the insulating material 111, which is only one example, and therefore the glass plate 113 may be bonded to only one surface of the insulating material 111.

Further, as illustrated in FIG. 2, the insulating materials 111 may be also bonded to both surfaces of the glass plate 113.

As such, the insulating material 111 performs a shock absorption function by bonding the insulating material 111 to the glass plate 113 to be able to prevent the glass plate from being damaged during a manufacturing process.

In this case, the preparing of the composite sheet 110 may include disposing the glass plates 113 on both surfaces of the insulating material 111 and bonding the glass plates 113 on both surfaces of the insulating material 111 by a heating process and a pressing process, but the preferred embodiment of the present invention is not particularly limited thereto.

Meanwhile, the preparing of the composite sheet 110 having the structure as illustrated in FIG. 2 may be performed by disposing the insulating materials 111 on both surfaces of the glass plate 113 and then bonding the insulating materials 111 on both surfaces of the glass plate 113 by the heating process and the pressing process.

Next, referring to FIG. 4, a via hole 110a which penetrates through the composite sheet 110 is formed.

In this case, the via hole 110a may be formed by a laser drill, but the preferred embodiment of the present invention is not particularly limited thereto.

Here, as the laser drill, a CO2 laser, a YAG laser, a pulse UV excimer laser, and the like may be used, but the preferred embodiment of the present invention is not particularly limited thereto.

Next, although not illustrated in the drawing, the method for manufacturing a printed circuit board may further include cleaning the surface of the composite sheet 110 on which the via hole 110a is formed and an inner wall of the via hole 110a.

In this case, the cleaning may be performed by a dry etching process or a wet etching process, but the preferred embodiment of the present invention is not particularly limited thereto.

In detail, as the dry etching process, plasma etching, sputter etching, ion etching, and the like may be used, but the preferred embodiment of the present invention is not limited thereto.

Next, referring to FIG. 5, the seed layer 121 is formed on the composite sheet 110, including the inner wall of the via hole 110a.

Herein, the seed layer 121 is formed to perform an electroplating method for forming the plating layer 123 in the subsequent process.

According to the present embodiment, the seed layer 121 may be formed by the sputtering method, but the preferred embodiment of the present invention is not particularly limited thereto.

Further, according to the preferred embodiment of the present invention, the seed layer 121 may be made of any one selected from a group consisting of titanium (Ti), aluminum (Al), copper (Cu), molybdenum (Mo), nickel (Ni), silver (Ag), zinc (Zn), carbon (C) or an alloy thereof, but the preferred embodiment of the present invention is not particularly limited thereto.

Further, according to the preferred embodiment of the present invention, as illustrated in FIG. 4, the seed layer 121 may include the first seed layer 121a which is formed on the surface of the composite sheet 110 and the second seed layer 121b which is formed on the first seed layer 121a.

In this case, the first seed layer 121a and the second seed layer 121b may each be formed by the sputtering method, but the preferred embodiment of the present invention is not particularly limited thereto and may be made of any one selected from a group consisting of titanium (Ti), aluminum (Al), copper (Cu), molybdenum (Mo), nickel (Ni), silver (Ag), zinc (Zn), carbon (C) or an alloy thereof, but the preferred embodiment of the present invention is not particularly limited thereto.

Next, referring to FIG. 6, a plating resist 130 having an opening 130a for circuit formation is formed on the seed layer 121.

In this case, a method for forming the plating resist 130 having the opening 130a for circuit formation is not illustrated in the drawing, which is a technology known to the art and therefore the detailed description thereof will be omitted.

Next, referring to FIGS. 7 and 8, the plating layer 123 is formed in the opening 130a for circuit formation by performing the plating process and then the plating resist 130 is removed.

Here, the plating process may be an electroplating method, but the preferred embodiment of the present invention is not limited thereto.

Further, the plating layer 123 may be made of copper (Cu), but the preferred embodiment of the present invention is not particularly limited thereto.

Further, the removing of the plating resist 130 may be performed by a mechanical delamination process or a chemical delamination process using a stripping liquid, but the preferred embodiment of the present invention is not limited thereto.

Next, although not illustrated in the drawing, the multi-layer printed circuit board may also be manufactured by forming the build-up layer (not illustrated) including the plurality of insulating layers and the plurality of circuit layers on the composite sheet 110 on which the circuit layer 120 is formed.

In this case, similar to the composite sheet 110 according to the preferred embodiment of the present invention, each of the plurality of insulating layers may have a structure in which the glass plate 113 is formed on one surface or both surfaces of the insulating material 111 made of polymer having heat resistance, but the preferred embodiment of the present invention is not particularly limited thereto, and therefore any material widely used as the insulating layer in the art may be used.

According to the preferred embodiments of the present invention, the printed circuit board is manufactured by using the composite sheet in which the glass plates having excellent rigidity are bonded to both surfaces of an insulating material, such that even though the printed circuit board is manufactured to have the thin thickness, the printed circuit board may have the excellent rigidity and the strain of the printed circuit board depending on the change in temperature and humidity may be minimized.

Further, according to the preferred embodiments of the present invention, the insulating material is bonded to the glass plate to allow the insulating material to perform a shock absorption function, thereby preventing the glass plate from being damaged during the manufacturing process.

In addition, according to the preferred embodiments of the present invention, the circuit layer is formed on the smooth glass plate to prevent the roughness from being formed at the interface between the glass plate and the circuit layer, thereby easily implementing the circuit having the less signal noise and the ultrafine pitch.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A printed circuit board, comprising:
a composite sheet including an insulating material and a glass plate bonded to the insulating material; and
a circuit layer formed on the composite sheet.

2. The printed circuit board as set forth in claim 1, wherein the composite sheet has a structure in which the glass plate is bonded to one surface or both surfaces of the insulating material.

3. The printed circuit board as set forth in claim 1, wherein the composite sheet has a structure in which the insulating material is bonded to one surface or both surfaces of the glass plate.

4. The printed circuit board as set forth in claim 1, wherein the circuit layer includes:
a circuit pattern formed on the composite sheet; and
a via formed to penetrate through the composite sheet.

5. The printed circuit board as set forth in claim 1, wherein the circuit layer includes:
a seed layer formed on a surface of the composite sheet; and
a plating layer formed on the seed layer.

6. The printed circuit board as set forth in claim 5, wherein the seed layer is made of any one selected from a group consisting of titanium (Ti), aluminum (Al), copper (Cu), molybdenum (Mo), nickel (Ni), silver (Ag), zinc (Zn), carbon (C) or an alloy thereof.

7. The printed circuit board as set forth in claim 5, wherein the seed layer includes:
a first seed layer formed on the surface of the composite sheet; and
a second seed layer formed on the first seed layer.

8. The printed circuit board as set forth in claim 1, wherein the insulating material is made of polymer having heat resistance.

9. The printed circuit board as set forth in claim 1, wherein the insulating material includes any one selected from a group consisting of liquid crystal polymer (LCP), polyethylene terephthalate (PET), polyethylene naphthalate (PEN), polyurethane (PU), epoxy in which glass fabric is impregnated, and polyimide.

10. A method for manufacturing a printed circuit board, comprising:
preparing a composite sheet in which a glass plate is bonded to an insulating material;
forming a seed layer on the composite sheet;
forming a plating resist having an opening for circuit formation on the seed layer;
forming a plating layer in the opening by a plating process; and
removing the plating resist.

11. The method for a printed circuit board as set forth in claim 10, wherein the preparing of the composite sheet includes:
disposing the glass plate on one surface or both surfaces of the insulating material; and
bonding the insulating material to the glass plate by a heating process and a pressing process.

12. The method for a printed circuit board as set forth in claim 10, wherein the preparing of the composite sheet includes:
disposing the insulating material on one surface or both surfaces of the glass plate; and
bonding the insulating material to the glass plate by a heating process and a pressing process.

13. The method for a printed circuit board as set forth in claim 10, wherein the forming of the seed layer is performed by a sputtering method.

14. The method for a printed circuit board as set forth in claim 10, wherein the forming of the seed layer includes:
forming a first seed layer on a surface of the composite sheet; and
forming a second seed layer on the first seed layer.

15. The method for a printed circuit board as set forth in claim 10, further comprising:
prior to the forming of the seed layer, machining a via hole penetrating through the composite sheet.

16. The method for a printed circuit board as set forth in claim 15, wherein the machining of the via hole is performed using a laser drill.

17. The method for a printed circuit board as set forth in claim 15, further comprising:
after the machining of the via hole, cleaning the surface of the composite sheet and an inside of the via hole.

18. The method for a printed circuit board as set forth in claim 17, wherein the cleaning is performed by dry etching or wet etching.
